(19) United States
(12) Patent Application Publication
(10) Pub. No.: US 2013/0299148 A1
(43) Pub. Date: Nov. 14, 2013

(54) MONOLITHIC STRUCTURALLY COMPLEX HEAT SINK DESIGNS

(71) Applicant: Alcatel-Lucent USA Inc., Murray Hill, NJ (US)

(72) Inventors: Domhnaill Hernon, Murray Hill, NJ (US); Alan Lyons, Murray Hill, NJ (US); Shankar Krishnan, Murray Hill, NJ (US); Marc Hodes, Murray Hill, NJ (US); Alan O'Loughlin, Murray Hill, NJ (US)

(21) Appl. No.: 13/941,314

(22) Filed: Jul. 12, 2013

Related U.S. Application Data
(63) Continuation of application No. 12/165,225, filed on Jun. 30, 2008.

(51) Int. Cl. H05K 7/20; B22D 25/02; F28F 13/00

(52) U.S. Cl. CPC H05K 7/20009; F28F 13/003; B22D 25/02
USPC 165/168; 165/185; 29/890.03; 164/47

(57) ABSTRACT

A heat sink includes a base and a heat exchange element coupled to the base. The heat exchange element includes a foam structure that is coupled to the base.

### CROSS-REFERENCE TO RELATED APPLICATIONS

This application is a continuation of U.S. patent application Ser. No. 12/165,225, entitled “Monolithic Structurally Complex Heat Sink Designs”, filed on Jun. 30, 2008, which is commonly assigned with the present invention and is incorporated herein by reference as if reproduced herein in its entirety, as well as is related to U.S. patent application Ser. No. 12/165,063 to Hernon, et al., entitled “Active Heat Sink Designs” (hereinafter, “Hernon 1”) and U.S. patent application Ser. No. 12/165,193 to Hernon, et al., entitled “Flow Diverters to Enhance Heat Sink Performance” (hereinafter, “Hernon 2”), all of which are hereby incorporated by reference as if reproduced herein in their entirety.

### TECHNICAL FIELD OF THE INVENTION

The present invention is directed, in general, to heat sinks.

### BACKGROUND OF THE INVENTION

Heat sinks are commonly used to increase the convective surface area of an electronic device to decrease the thermal resistance between the device and a cooling medium, e.g., air. Various manufacturing methods are used, including extrusion, machining and die-casting. These methods are suitable for relatively simple heat sinks. But more complex structures are needed to improve the performance of heat sinks. Traditional methods of manufacturing heat sinks are not suited to making such complex structures.

### SUMMARY OF THE INVENTION

One embodiment is a heat sink that includes a base and a heat exchange element coupled to the base. The heat exchange element includes a foam structure coupled to the base.

Another embodiment is a method that includes providing a sacrificial heat sink pattern comprising a base form and a heat exchange element form connected to the base form. The heat exchange element form includes a foam structure coupled to the base. The pattern is provided to an investment casting process to form a monolithic heat sink.

### BRIEF DESCRIPTION OF THE DRAWINGS

Various embodiments are understood from the following detailed description, when read with the accompanying figures. Various features may not be drawn to scale and may be arbitrarily increased or reduced in size for clarity of discussion. Various features in figures may be described as “vertical” or “horizontal” for convenience in referring to those features. Such descriptions do not limit the orientation of such features with respect to the natural horizon or gravity. Reference is now made to the following descriptions taken in conjunction with the accompanying drawings, in which:

FIG. 1 illustrates a prior art heat sink;

FIG. 2 illustrates elements of heat sinks in accordance with the invention;

FIG. 3 illustrates a method;

FIG. 4 illustrates a periodic fin-foam heat sink;

FIG. 5A illustrates a minimum-surface structure heat sink;

FIG. 5B illustrates a path with varying cross-sectional area;

FIG. 6 illustrates a slotted honeycomb heat sink;

FIGS. 7A, 7B and 7C respectively illustrate elements of the embodiments of FIGS. 4, 5A and 6; and

FIG. 8 illustrates performance characteristics of heat sinks.

### DETAILED DESCRIPTION OF ILLUSTRATIVE EMBODIMENTS

Embodiments described herein reflect the recognition that three dimensional (3-D) rendering and investment casting may be employed to manufacture monolithic heat sinks with structural complexity unattainable by prior art methods. Such complexity in a monolithic heat sink design provides a means to form heat sinks with novel structural features to improve the performance of such heat sinks over prior art heat sinks. The described embodiments make structural elements available to heat sink designers hitherto unattainable. The availability of these elements provides the designer with the ability to take greater advantage of flow mechanics and heat dissipation physics than with “simple” heat sinks, defined below. Embodiments are described herein that result in a significant improvement of heat transfer characteristics of a structurally complex heat sink relative to simple heat sinks.

The present discussion introduces the concept of using 3-D printing of a sacrificial pattern and subsequent investment casting to form a heat sink in which heat exchange elements can be monolithically attached to a base of the heat sink. As used herein, monolithic is defined with respect to an element of a heat sink to mean that the element and base are a single, continuous entity. In other words, the element and the base are portions of a single, cast unit, and are not fastened to the remaining portion by adhesive, screws, welds, crimps, or any similar chemical or mechanical means. However, a heat exchange element and base are still monolithically connected if they are polycrystalline, if any of these fastening means are used to attach another element to the monolithic portion or to attach the heat sink to a circuit or assembly.

A typical 3-D printer uses a laser and a liquid photopolymer to produce a 3-D form by a succession of solid layers. An example is a stereolithography rapid prototyping system. Those skilled in the pertinent art are familiar with such systems and the photopolymers used in them. For example, one type of printer uses the laser to produce a solid pattern in a thin layer of liquid photopolymer on a translatable stage. The stage is advanced and another layer is formed on the first layer. By a succession of layers, a 3-D form of an object of almost arbitrary complexity may be formed with potential resolution of features on the order of 100 μm. In some systems, a wax or soluble photopolymer is also used to mechanically support fragile portions of the 3-D form. The 3-D form may be used directly as a pattern in a conventional investment casting process described further below.

Heat sinks formed using patterns generated by 3-D printing are referred to herein as “structurally complex” heat sinks to reflect the potential for structural complexity. It is understood, however, that the presence of specific physical features is not a prerequisite to including a heat sink in the class of complex heat sinks defined here.

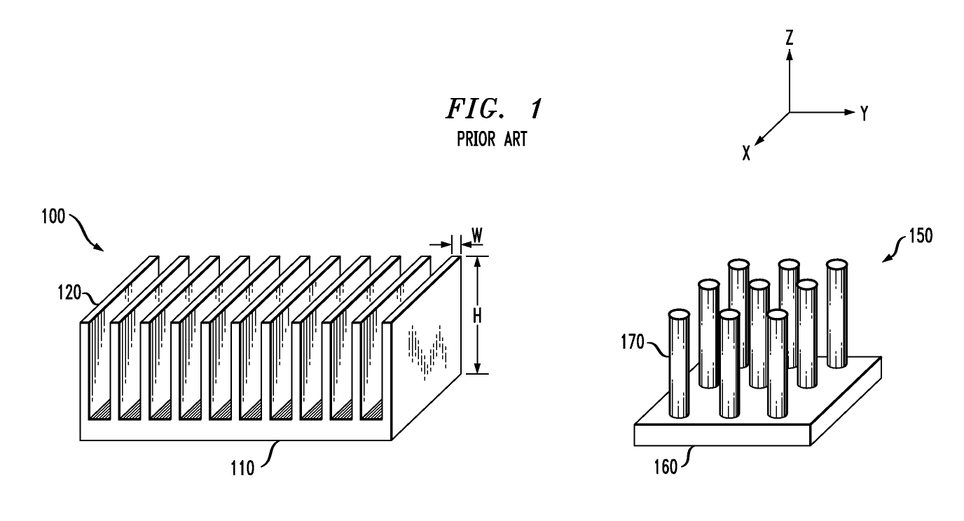

FIG. 1 illustrates a prior art heat sink 100. Features of the heat sink 100 include a base 110 and fins 120. The fins 120 are structurally uniform, e.g., there are no projections from or depressions in the surface of the fins 120 other than surface roughness typical of the particular manufacturing method. The heat sink 100 is representative of the class of heat sinks formed by conventional methods including extrusion, sand-casting, die-casting, bonding, folding, forging, skiving and machining of metal blocks or sacrificial forms. Machining is defined as the removal of material from a block by mechanical means. The maximum aspect ratio of the fins, i.e., the ratio of the fin height H to fin thickness T, is typically limited to a range of about 8:1 to about 20:1, depending on the manufacturing method. Heat sinks in this class are defined herein as “simple” heat sinks, and are expressly disclaimed.

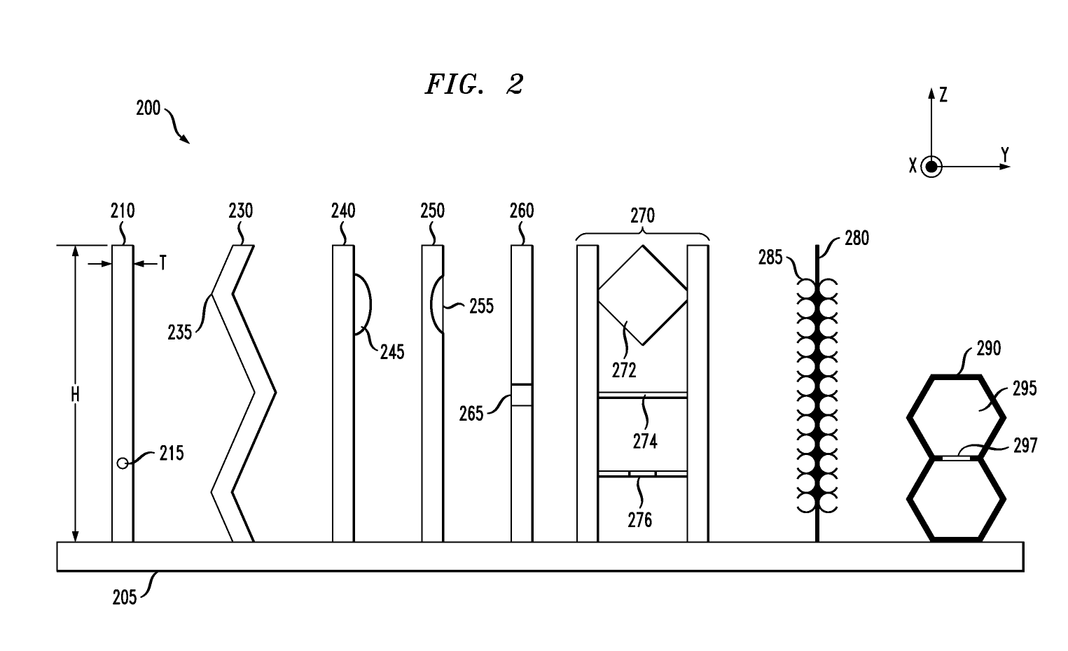

FIG. 2 illustrates various structural features of a structurally complex heat sink 200 that may be formed using 3-D printing and casting. Coordinate axes are shown for reference in the following discussion. A base 205 provides a foundation for various illustrated heat exchange elements. The base is shown as planar, but may be any desired shape. For example, a base may be formed in a shape that conforms to underlying topography of a circuit board or electronic device. Several examples of heat exchange elements are illustrated in FIG. 2. It is noted that these examples are not exclusive, and that the heat sink 200 may include each type of element alone or in combination with other elements.

A fin 210 is a rectangular solid element projecting from the base 205. The fin may have a conventional aspect ratio, (the ratio of the height to the thickness) less than about 20:1, or may have a greater aspect ratio. The fin 210 may include a coolant channel 215 through which a coolant such as, e.g., water or air, may be circulated to augment heat transfer from the fin to, e.g., an air stream adjacent to the fin 210. The coolant channel may be routed in a manner not achievable by prior art methods of forming heat sinks, e.g., in an arbitrary path in the X-Z plane. Such channels may also be provided in the base 205 if desired. The aspect ratio of the fin 210 may be limited by such factors as, e.g., material strength, ability to fill high aspect ratio voids during casting, and mechanical strength required of the fins to withstand loads during service. It is conservatively estimated that fins may be constructed with an aspect ratio exceeding 100:1.

A fin 230 includes bends 235 formed in the Y-Z plane. Such bends may be desirable to, e.g., increase fin surface area without increasing fin height above the base 205. Depending on complexity, the bends 235 may be difficult to manufacture by the aforementioned methods, especially if combined with other features illustrated in FIG. 2. For example, bends may be formed in both the Y-Z and the X-Y planes. The conventional manufacturing methods are not amenable to such structurally complex features.

In another embodiment, a fin 240 includes an extension 245. The extension 245 may be thin in the X-direction, in which case the minimum thickness will depend on factors including the material used for the heat sink. The thickness in the X-direction may range from this minimum to greater than the full length of the fin 240 in the X-direction. The thickness in the X-direction may exceed the length of the fin 240 when, e.g., the extension 245 forms a portion of a vortex generator placed upwind of the heat sink 200. See, e.g., U.S. patent application Ser. No. 12/165,193 (Hernon 2). The height of the extension 245 in the Z-direction may range from a minimum formable thickness to greater than the height of the fin 240. In some embodiments, the extension forms a flat plate, e.g., a thin planar feature projecting from the fin 240 into an air stream flowing past the fin 240. The extension 245 configured in this way may be, e.g., a flow diverter as described in the Hernon 2 application. In other embodiments, the extension forms a bump, which may be circular, elliptical, or pyramidal, e.g.

A fin 250 includes a depression 255. The depression 255 may be, e.g., a dimple having circular or elliptical cross-section in the X-Z plane. The profile of the depression 255 in the Y-Z plane may be any desired profile, such as, e.g., circular (as illustrated), triangular, square, or even a re-entrant cavity. As was described for the extension 245, the depression 255 may also extend in the X-direction the entire length of the fin 250, or in the Z-direction for the entire height of the fin 250.

A fin 260 includes an opening 265. The opening 265 intersects both opposing surfaces of the fin 260. The opening 265 may be any desired shape, e.g., circular, triangular, square or hexagonal, and the fin 260 may include any desired number of openings 265. Of course, the configuration of openings 265 may be constrained by the mechanical strength of the material used, the fin thickness, and the service environment to preserve the physical integrity of the fin 265.

Fins 270 include bridging elements 272, 274, 276. Such bridging elements may be oriented such that a major surface is oriented, e.g., in the Y-Z plane, such as bridging element 272, or in the X-Y plane, such as bridging element 274. Bridging features may also include openings, such as bridging element 276. Bridging elements may also be used to form ducts to direct air from one portion of the heat sink to another. See, e.g., U.S. patent application Ser. No. 12/165,225 (hereinafter, “Hernon 3”).

Fin 280 includes re-entrant voids 285. The voids 285 have a concave volume accessible only through an opening that is smaller than the largest cross-sectional area of the void. Such features provide a means to significantly increase the surface area of the fin 280 to reduce thermal resistance between the fin 280 and the ambient. Novel heat sink structures such as a minimum area surface may also be produced, as described below.

In some cases, fins are not even used. Honeycomb channels 290 are one such heat exchange element. In this embodiment, channels 295 formed by the honeycomb run parallel to each other and to the base 205. The channels 295 are closed channels, meaning the cross-section of each channel is a closed polygon at some point along the channel. The walls of the channels 295 may include other features already described, including, e.g., openings 297, extensions and depressions. As the term “closed channel” is used herein, a channel may include openings such as the openings 297 in the channel walls and still be considered closed.

The foregoing physical features are not exhaustive of the possible features that may be formed by the described method. Moreover, the elements described may be combined in innovative ways to achieve heat transfer characteristics hitherto unobtainable. The advantages provided by the possible combinations of elements are extended by the fact that these elements are integral to the monolithic heat sink 200. Thus the elements are not partially insulated from the heat sink by thermal grease or an adhesive material, and thermal conductivity throughout the heat sink is improved. Moreover, the homogeneous thermal conductivity of the heat sink may provide a more consistent environment for modeling of the thermal performance of the heat sink, easing the design burden. The advantages of forming an element and a base as a monolithic structure are not lost if additional structural elements are attached to the heat sink in a non-monolithic manner.

Heat sinks formed by the described embodiments are intended for applications in which machining of features of a complex heat sink are impractical, uneconomical or impossible. As such, the target applications are limited to those in which physical dimensions of features of the heat sink are below a size for which machining may be economically and practically used. Certainly, machining of features on surfaces of a heat sink separated by 1 mm or less is considered impractical, uneconomical or impossible. Such machining when surfaces are separated by 5 mm would still be considered at least impractical or uneconomical, and may be infeasible. Above 1 cm, machining might be feasible, even if at great expense, in the most demanding applications. Accordingly, heat sinks are expressly disclaimed that have opposing surfaces separated by more than about 1 cm.

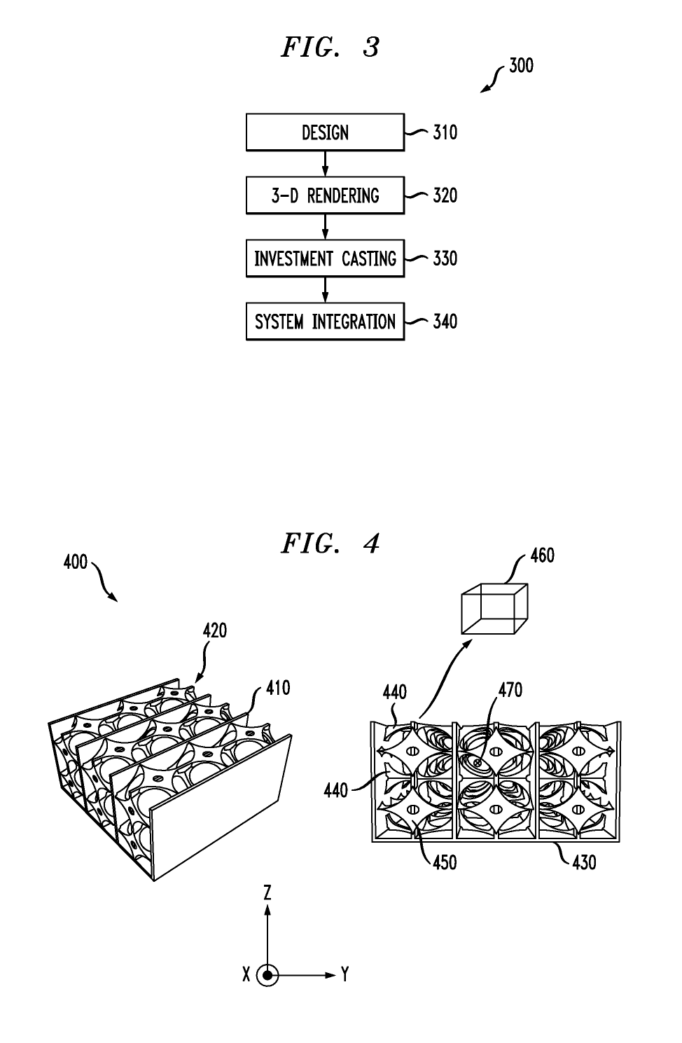

FIG. 3 illustrates a method 300 for forming a structurally complex heat sink. In a step 310, a designer reduces a concept to a design. The heat sink may be designed in any manner amenable to later transfer of design data to a 3-D rendering system. One particularly useful technique includes the use of a 3-D computer-aided design and manufacturing (CAD/CAM) system to define the structure of the structurally complex heat sink. Data provided by the CAD/CAM system may be provided directly to a 3-D rendering system in a step 320. The data may also be advantageously provided to a thermal modeling system to predict and optimize the performance of the heat sink design under various conditions such as air speed, thermal load and maximum heat flux. While thermal modeling may be advantageous during the design phase of the heat sink, it should be understood that the method 300 does not require such modeling.

In the step 320, the design resulting from the step 310 is rendered as a heat sink form in a sacrificial material. The material may be, e.g., a photopolymer used in a stereolithography rapid prototyping system. A base form and a heat exchange form may be produced as a monolithic pattern. The resulting pattern may be of almost arbitrary complexity. In those cases which a single pattern cannot capture a desired design two or more forms may be joined to produce the final desired pattern.

In a step 330, the heat sink is rendered in a desired metal using the pattern produced in the step 320 as a sacrificial form in an investment casting process. Those skilled in the art of investment casting are familiar with various methods of investment casting. In a preferred embodiment, a phosphoric acid bonded plaster casting method is used.

In a step 340, the heat sink is integrated into a system, such as an electronic assembly. In some cases, the heat sink is joined to an electronic component, e.g., an integrated circuit such as a microprocessor or power amplifier, an optical amplifier, or similar heat-dissipating device. In some cases, the heat sink could be attached to the cold side of a thermo-electric device when the warm side is used to heat a device. Thermal grease or a heat conducting pad may be used to improve thermal conduction between the device package and the heat sink. In other cases, cooling lines may be attached to the heat sink when liquid coolant channels such as the coolant channel 245 are provided in the heat sink.

The following embodiments are non-limiting applications of the described method of forming a monolithic heat sink. These applications illustrate the use of various structural features previously described and illustrated in FIG. 2. It is understood, however, that any heat sink design not otherwise disclaimed and including structural features such as those illustrated in FIG. 2 and formed by the described method are within the scope of this disclosure.

Turning to FIG. 4, illustrated is an embodiment of a fin-foam heat sink 400. The fin-foam heat sink 400 includes vertical fins 410 and a foam structure 420 on a base 430. The foam structure 420 is a structurally complex assemblage of heat transfer elements having a porous structure that fills space in a heat sink. When a foam structure is combined with heat sink fins, the combined structure is referred to as a fin-foam.

In some cases, the foam structures are unstructured (pseudo-random). In other cases, the foam structures have one or more heat transfer elements configured in unit cells with two- or three-dimensional periodicity. In FIG. 4, e.g., X-Y elements 440 have a major surface that is about parallel to the X-Y plane as denoted by the XYZ coordinate reference, and Y-Z elements 450 have a major surface that is about parallel to the Y-Z plane. A unit cell 460 in this nonlimiting example includes one Y-Z element and two X-Z elements.

The heat transfer elements are configured to provide a path 470 for air flow through the heat sink 400. In some cases, the path 470 is an unobstructed path, meaning that the path 470 provides a straight-line route for air flow through the heat sink 400 that may additionally be parallel to the base 430. In other cases, the path 470 is a tortuous path, meaning that a route of air flow through the heat sink 400 includes bends. The mean path of the tortuous path is about parallel to the base 430. A particular heat sink design, such as the illustrated fin-foam design, may include a combination of unobstructed and tortuous paths.

In the fin-foam heat sink 400 the distance between the vertical fins 410 is equal to the unit cell width, but in other embodiments, the unit cell width may be smaller than this distance. For example, the space between the fins 410 may include two or more unit cells. In some embodiments the fins 410 are omitted completely, so the heat sink consists only of the foam structure 420 on the base 430. When a periodic foam structure is desired, the foam structures may be generated with body-centered cubic (BCC), face-centered cubic (FCC), A15 lattice arrangements, e.g., or any other desired lattice arrangement. The foam may include fractal geometries, or plates or spikes projecting from a horizontal or vertical plate to increase surface area for heat exchange.

The foam structures may also be designed to produce beneficial flow characteristics downstream of the foam voids within the fin passages. Such structures may be configured to produce, e.g., flow instabilities, unsteady laminar, transitional, turbulent, chaotic and resonant flows that increase heat transfer between the fin-foam heat sink 400 and the ambient. See, e.g., U.S. patent application Ser. No. 12/165,193 (Hernon 2).

The fins 410 and the foam structure 420 may be formed as a single, monolithic cast structure by the casting process described above. Such a design provides a significant advantage over a heat sink assembled from separate subassemblies in that there are no thermal resistance penalties associated with having extra thermal barriers due to adhesives, e.g. The fin-foam embodiment results in a significant increase of the surface area available for heat transfer to or from the fin-foam heat sink 400 compared to a simple heat sink design. For example, the surface area available for heat transfer on the fin-foam heat sink 400 is approximately 15% greater than the surface area of a parallel fin heat sink with identical length, height and width dimensions.

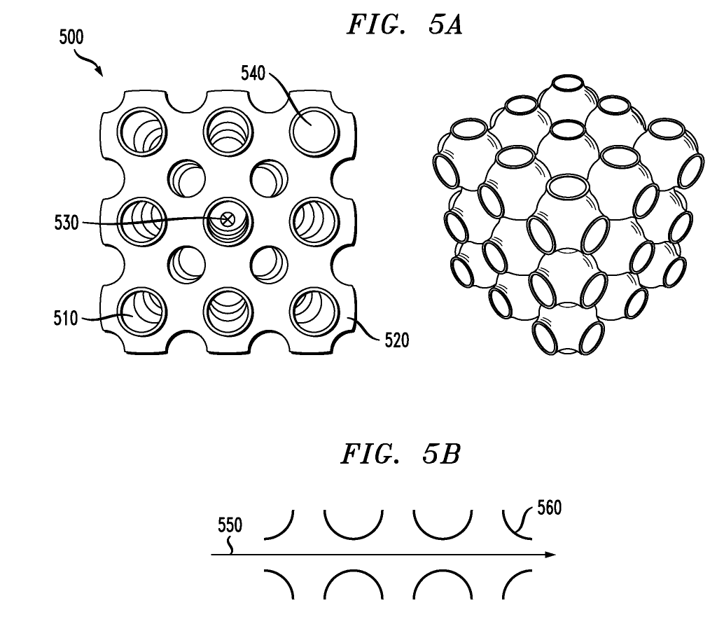

Turning now to FIG. 5, illustrated is an embodiment of a heat sink element 500 having only one interior surface 510 and one exterior surface 520. The illustrated embodiment is referred to as a Schwarz' P surface, and is characterized by smoothly varying curvature of the surfaces. Formally, the Schwarz' P structure is characterized by having zero mean curvature, and is sometimes referred to as a “minimum-surface” structure. Of course, other structures besides a Schwarz' P structure may be used, need not be area-minimizing, and may include flat or angular features.

The element 500 may comprise any shape or size of unit cell that includes an interior and an exterior volume separated by a continuously-connected surface, e.g., the Schwarz' P structure. The element 500 divides space into two congruent labyrinths. The element 500 also provides an unobstructed path 530. In some embodiments, the internal flow within the element 500 is disrupted by general instability through separation effects or simple acceleration and deceleration effects due to changes of cross-sectional area within the internal flow passages. Also, the unit cell need not be symmetric, but may be an arbitrary array of structures that may, e.g., sustain self-oscillations of flow.

The interior surface 510 defines an interior region and the exterior surface 520 defines an exterior region. The element 500 may be used in forced-air applications, in which case air flows over both the interior and exterior surfaces for cooling. In other cases, the element 500 may be used in liquid-cooled applications, in which a liquid coolant is caused to flow through the inner region. If desired, one or more caps 540 may be used to direct or limit fluid flow. The cap 540 may be, e.g., an active element as disclosed in U.S. patent application Ser. No. 12/165,063 (Hernon 1). In one embodiment, more air or cooling fluid may be directed to a portion of the element near an area of an electronic device dissipating greater power than other areas of the device. Varying the minimum or maximum diameter of passages through the element 500 may also be employed to preferentially direct the flow of air or a liquid.

Turning to FIG. 5B, a path 550 of a cooling fluid such as air through a channel cross-section 560 is illustrated. The nonlimiting case of the Schwartz' P structure is illustrated as an example. One aspect of such structures is that the width of a channel through which a fluid moves through the heat sink varies along the path of flow. In some embodiments, the structure is configured to be conducive to self-sustaining flow oscillations in the laminar flow regime. Such oscillations may be used to enhance heat transfer without large increases in flow resistance. Such structures may also trigger instabilities such as Tollmien-Schlichting waves or Kelvin-Helmholtz instabilities, or may trigger transition to turbulence.

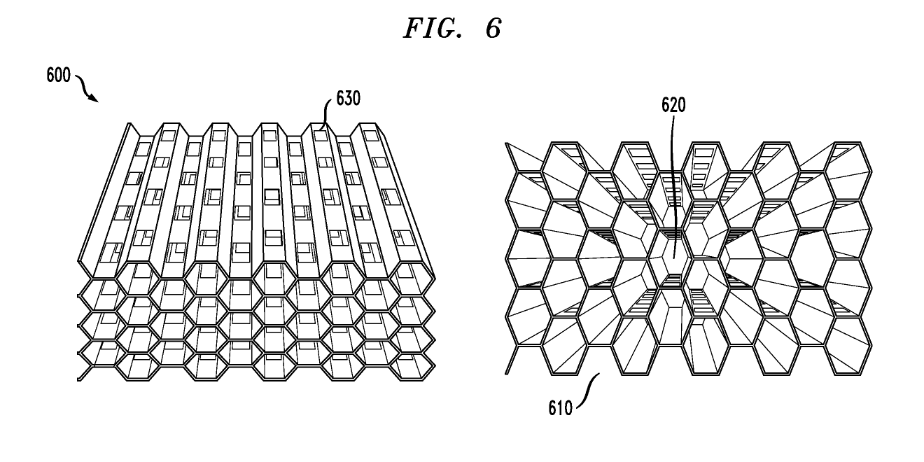

Turning now to FIG. 6, illustrated is an embodiment of a monolithic heat sink element 600. The element 600 may be used, e.g., as a finless heat sink, or as a heat transfer element between fins (not shown). The element 600 includes a base 610, parallel channels 620 and openings 630. The channels 620 have a hexagonal cross-section, and collectively form a honeycomb-like pattern. Other shapes that form a closed polygonal cross-section may also be used, e.g., square, triangular or circular channels. The parallel channels 620 provide unobstructed paths through the heat sink element 600.

The openings 630 may be, e.g., offset (staggered) rectangular or circular, or they may be otherwise positioned along the length of the channels 620 in a manner beneficial to the heat transfer and pressure characteristics of the element 600. It is thought that in some cases the openings 630 may improve convection or air flow away from the base 610. In some cases, the openings 630 may reduce thermal resistance between the heat sink and a cooling fluid by restarting a boundary layer region adjacent to the walls of the channels 620. The boundary layer is a region of relatively static air adjacent the channel wall that acts as a thermal insulator. Restarting the boundary layer may cause free-stream air to flow closer to the channel wall thereby increasing heat transfer. Complex geometries such as those shown in FIG. 6 that result in such flow effects are not achievable at the scale of component heat sinks using the conventional processes described previously.

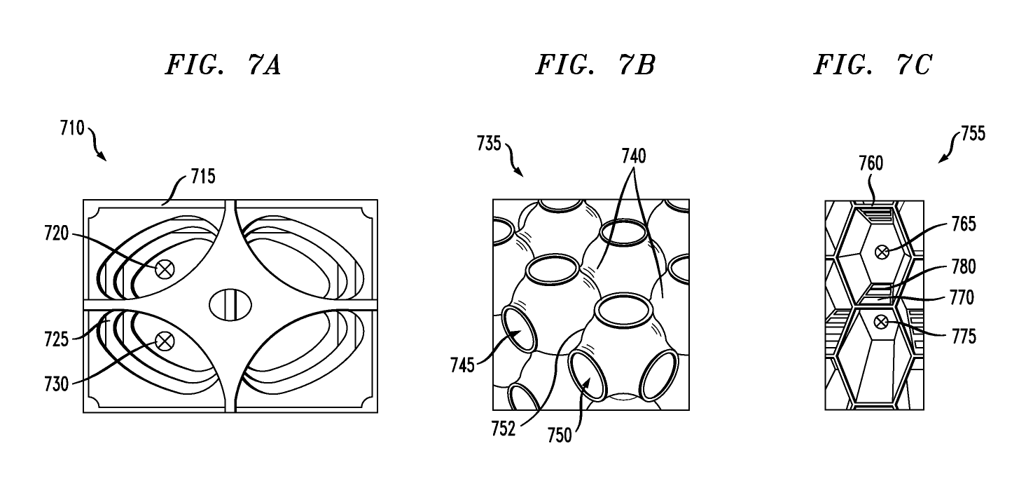

FIG. 7 illustrates a geometrical features shared by the described embodiments. FIG. 7A shows a detail 710 of the foam structure 420. FIG. 7B shows a detail 735 of the Schwartz' P structure of the heat sink element 500. FIG. 7C shows a detail 735 of the channel 620 of the heat sink element 600. Each detail 710, 735, 755 has a surface that at least partially bounds adjacent paths through the respective heat exchange element. A surface of a heat sink includes all surface area thereof, whether contiguous or non-contiguous.

Focusing first on the detail 710, the underside of a foam element 715 is a surface that partially bounds and forms an upper boundary of a path 720 through the foam structure 420. The underside of a foam element 725 is a surface that partially bounds and forms an upper boundary of a path 730 through the foam structure 420 that is adjacent to the path 720. An opening, hidden from view, connects the path 720 and the path 730. With respect to the detail 735, the underside of a portion 740 of the heat sink element 500 is a surface that partially bounds and forms an upper boundary of a path 745 and a path 750 through the heat sink element 500. A neck region 752 forms an opening between the path 745 and the path 750. With respect to the detail 755, the underside of a portion 760 of the heat sink element 600 is a surface that partially bounds and forms an upper boundary of a path 765. The underside of a portion 770 of the heat sink element 600 is a surface that partially bounds and forms an upper boundary of a path 775. An opening 780 connects the path 760 and the path 765.

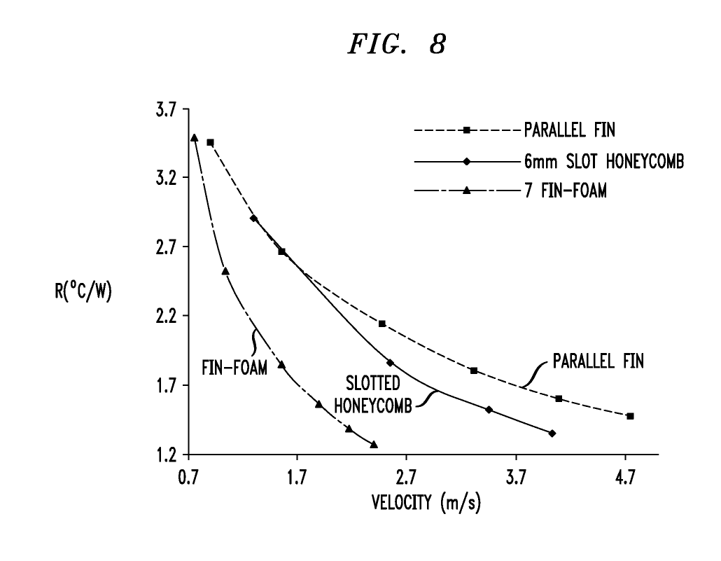

Turning to FIG. 8, illustrated is a graph comparing the experimental performance of a honeycomb heat sink, such as the heat sink 600, and a fin-foam heat sink, such as the heat sink 400 with a standard finned heat sink such as the heat sink 100. The performance curves show thermal resistance of the three cases as a function of air velocity directly upstream of the heat sinks. The heat sinks are controlled for heat sink width, height, length and heat sink base. All designs are placed in fully ducted flow, so that velocity through each heat sink is constant.

For the configurations tested, both the fin-foam and the honeycomb heat sinks outperform the finned heat sink, and the fin-foam heat sink outperforms the honeycomb design. While specific heat sink performance will depend on many factors, the performance characteristics clearly illustrate the potential benefit of the fin-foam design and the slotted honeycomb design over the traditional finned heat sink. This improvement over simple heat sinks is unexpectedly large. The magnitude of the improvement makes it possible to extend the use of air-cooled heat sinks to high power-dissipating electronic components that would otherwise require more expensive means of cooling, such as liquid cooling.

Although the present invention has been described in detail, those skilled in the art should understand that they can make various changes, substitutions and alterations herein without departing from the spirit and scope of the invention in its broadest form.

What is claimed is:

1. A heat sink, comprising:
a base; and
a heat exchange element comprising a foam structure coupled to the base.

2. The heat sink as recited in claim 1, wherein the heat exchange element is monolithically coupled to the base.

3. The heat sink as recited in claim 1, wherein the heat exchange element includes vertical fins to form a fin-foam structure.

4. The heat sink as recited in claim 3, wherein a distance between two adjacent fins is equal to a unit cell width of the foam structure.

5. The heat sink as recited in claim 3, wherein a unit cell width of the foam structure is smaller than a distance between two adjacent fins.

6. The heat sink as recited in claim 1, wherein the foam structure is pseudo-random.

7. The heat sink as recited in claim 1, wherein the foam structure includes one or more heat transfer elements configured in unit cells.

8. The heat sink as recited in claim 7, wherein the unit cells have three-dimensional periodicity.

9. The heat sink as recited in claim 1, wherein the foam structure is configured to provide a path for air flow through the heat sink, and further wherein the path is an unobstructed path.

10. The heat sink as recited in claim 1, wherein the foam structure is configured to provide a path for air flow through the heat sink, and further wherein the path is a tortuous path.

11. The heat sink as recited in claim 10, wherein a mean path of the tortuous path is about parallel to the base.

12. The heat sink as recited in claim 1, wherein the foam structure is configured to provide paths for air flow through the heat sink, and further wherein the paths include a combination of at least one unobstructed path and one tortuous path.

13. The heat sink as recited in claim 1, wherein the foam structure is a periodic foam structure.

14. The heat sink as recited in claim 13, wherein the periodic foam structure has an arrangement selected from the group consisting of:
a body-centered cubic (BCC) arrangement;
a face-centered cubic (FCC) arrangement; and
an A15 lattice arrangements arrangement.

15. The heat sink as recited in claim 1, wherein the foam structure includes fractal geometries, plates or spikes projecting from a horizontal or vertical plate thereof to increase surface area for heat exchange.

16. The heat sink as recited in claim 1, wherein the foam structure has a surface that at least partially bounds first and second paths through the heat exchange element.

17. A method comprising:
providing a sacrificial heat sink pattern comprising:
a base form; and
a heat exchange element form comprising a foam structure coupled to the base; and
providing the sacrificial heat sink pattern to an investment casting process to form a monolithic heat sink.

18. The method as recited in claim 17, wherein the heat exchange element form includes vertical fins to form a fin-foam structure form.

19. The method as recited in claim 17, wherein the foam structure form is configured to provide a path for air flow through the heat sink, and further wherein the path is a tortuous path.

20. The method as recited in claim 17, further comprising the step of forming said heat sink using stereolithography.
